(19) United States
(12) Patent Application Publication
(10) Pub. No.: US 2025/0250857 A1
(43) Pub. Date: Aug. 7, 2025

(54) ANTENNA FOR A MOTORIZED WINDOW TREATMENT

(71) Applicant: Lutron Technology Company LLC, Coopersburg, PA (US)

(72) Inventors: Richard S. Camden, Coopersburg, PA (US); Marissa Diehl, Breinigsville, PA (US); Daniel Fay, Allentown, PA (US); Charles Fiebig, Frenchtown, NJ (US); Christiana Malone, Allentown, PA (US)

(73) Assignee: Lutron Technology Company LLC, Coopersburg, PA (US)

(21) Appl. No.: 19/043,177

(22) Filed: Jan. 31, 2025

Related U.S. Application Data
(60) Provisional application No. 63/548,671, filed on Feb. 1, 2024.

(51) Int. Cl. E06B 9/72; E06B 9/50; H01Q 1/22; H01Q 1/42; H05K 1/02

(52) U.S. Cl. CPC E06B 9/72; E06B 9/50; H01Q 1/22; H01Q 1/42; H05K 1/025

(57) ABSTRACT

A motor drive unit for a motorized window treatment may comprise an antenna system for allowing the motor drive unit to transmit and/or receive wireless signals. The motor drive unit may comprise a housing configured to be received within a roller tube, a motor configured to rotate the roller tube, and a first printed circuit board. The first printed circuit board may have mounted thereto drive circuitry for controlling the motor and a wireless communication circuit for communicating messages via the wireless signals. The motor drive unit (e.g., the antenna system) may comprise an antenna element configured to transmit and receive wireless signals, and a second printed circuit board secured within the housing. The second printed circuit board may comprise an electrical conductor that extends along a length of the second printed circuit board and enables electrical communication between the antenna element and the wireless communication circuit.

### CROSS-REFERENCE TO RELATED APPLICATIONS

This application claims the benefit of Provisional U.S. Patent Application No. 63/548,671, filed Feb. 1, 2024, the entire disclosure of which is hereby incorporated by reference herein in its entirety.

### BACKGROUND

A window treatment may be mounted in front of one or more windows, for example to prevent sunlight from entering a space and/or to provide privacy. Window treatments may include, for example, roller shades, roman shades, venetian blinds, or draperies. A roller shade typically includes a flexible shade fabric wound onto an elongated roller tube. Such a roller shade may include a weighted hembar located at a lower end of the shade fabric. The hembar may cause the shade fabric to hang in front of one or more windows over which the roller shade is mounted.

A typical window treatment can be mounted to structure surrounding a window, such as a window frame. Such a window treatment may include brackets at opposed ends thereof. The brackets may be configured to operably support the roller tube, such that the flexible material may be raised and lowered. For example, the brackets may be configured to support respective ends of the roller tube. The brackets may be attached to structure, such as a wall, ceiling, window frame, or other structure.

Such a window treatment may be motorized. A motorized window treatment may include a roller tube, a motor, brackets, and electrical wiring. The components of the motorized window treatment, such as the brackets, the roller tube, electrical wiring, etc. may be concealed by a fascia or installed in a pocket out of view.

### SUMMARY

As described herein, a motor drive unit for a motorized window treatment may comprise an antenna system for allowing the motor drive unit to transmit and/or receive wireless signals. The motorized window treatment may have a roller tube configured to windingly receive a flexible material and to be rotated to raise and lower the flexible material. The motor drive unit may comprise a housing configured to be received within a cavity of the roller tube, a motor located within the housing and configured to rotate the roller tube, and a first printed circuit board located within the housing. The first printed circuit board may have mounted thereto drive circuitry for controlling the motor and a wireless communication circuit for communicating messages via the wireless signals. The motor drive unit (e.g., the antenna system of the motor drive unit) may comprise an antenna element configured to transmit and receive wireless signals, and a second printed circuit board mounted to the housing. The second printed circuit board may comprise an electrical conductor that extends along a length of a front side of the second printed circuit board. The electrical conductor enabling electrical communication between the antenna element and the wireless communication circuit mounted to the motor drive printed circuit board. The second printed circuit board may further comprise a first ground plane on a rear side of the second printed circuit board. The first and ground plane may be in electrical communication with a circuit common of the motor drive printed circuit board. The second printed circuit board may further comprise a second ground plane having a first portion located on a first side of the electrical conductor and a second portion located on a second side of the electrical conductor on the front side of the second printed circuit board. The wireless communication circuit may be configured to receive messages via the wireless signals received by the antenna element and transmit message via the wireless signals transmitted by the antenna element.

### BRIEF DESCRIPTION OF THE DRAWINGS

FIG. 1 is a perspective view of an example motorized window treatment in an operating position.

FIG. 2 is a perspective view of the example battery-powered motorized window treatment of FIG. 1 in an extended position.

FIG. 3 is a perspective view of the example battery-powered motorized window treatment of FIG. 1 in the extended position with batteries removed.

FIG. 4 is a front cross-sectional view of the example battery-powered motorized window treatment of FIG. 1.

FIG. 5 is an enlarged front cross-sectional view of another example motorized window treatment.

FIG. 6 is a perspective view of an example motor drive unit of the example motorized window treatment of FIG. 5.

FIG. 7 is an enlarged top perspective view of an end portion of the motor drive unit of FIG. 6.

FIG. 8 is an enlarged bottom perspective view of the end portion of the motor drive unit of FIG. 6.

FIG. 9 is an enlarged top perspective view of the end portion of the motor drive unit of FIG. 6 with an outer bearing of a bearing assembly of the motor drive unit removed.

FIG. 10 is a perspective view of the motor drive unit of FIG. 6 with a first portion of a body of a housing and a battery holder of the motor drive unit removed.

FIG. 11 is an enlarged perspective view of the motor drive unit of FIG. 6 with a first portion of a body of a housing and a battery holder of the motor drive unit removed.

FIG. 12A is a front view of a printed circuit board of the motor drive unit of FIG. 6 showing a front side of the printed circuit board.

FIG. 12B is a rear view of the printed circuit board of FIG. 12A showing a rear side of the printed circuit board.

FIG. 13A is a partial front view showing a first end of the printed circuit board of FIG. 12A.

FIG. 13B is a partial front view showing a second end of the printed circuit board of FIG. 12A.

FIG. 14 is a block diagram of an example motor drive unit of a motorized window treatment.

### DETAILED DESCRIPTION

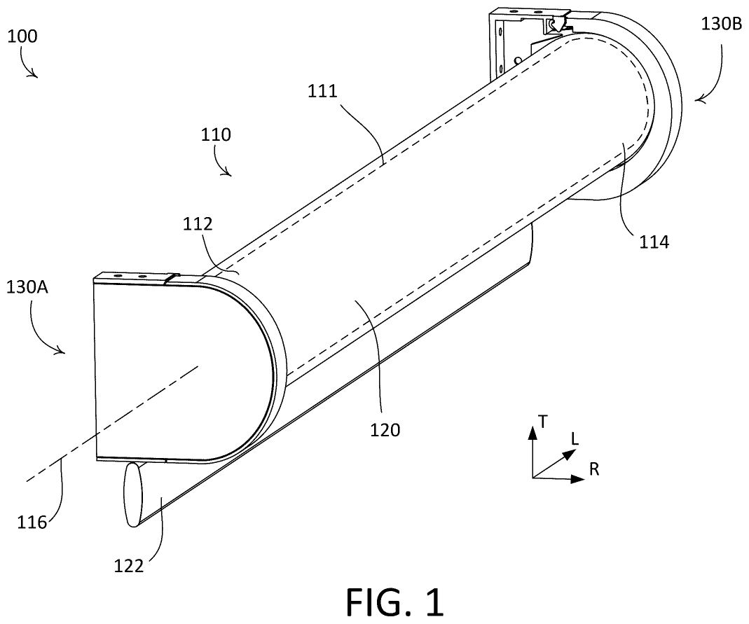

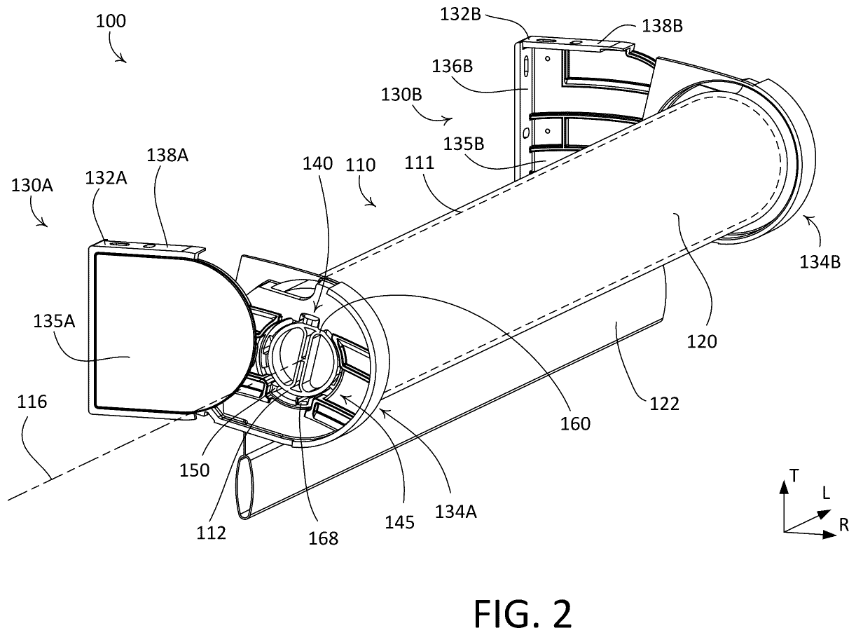

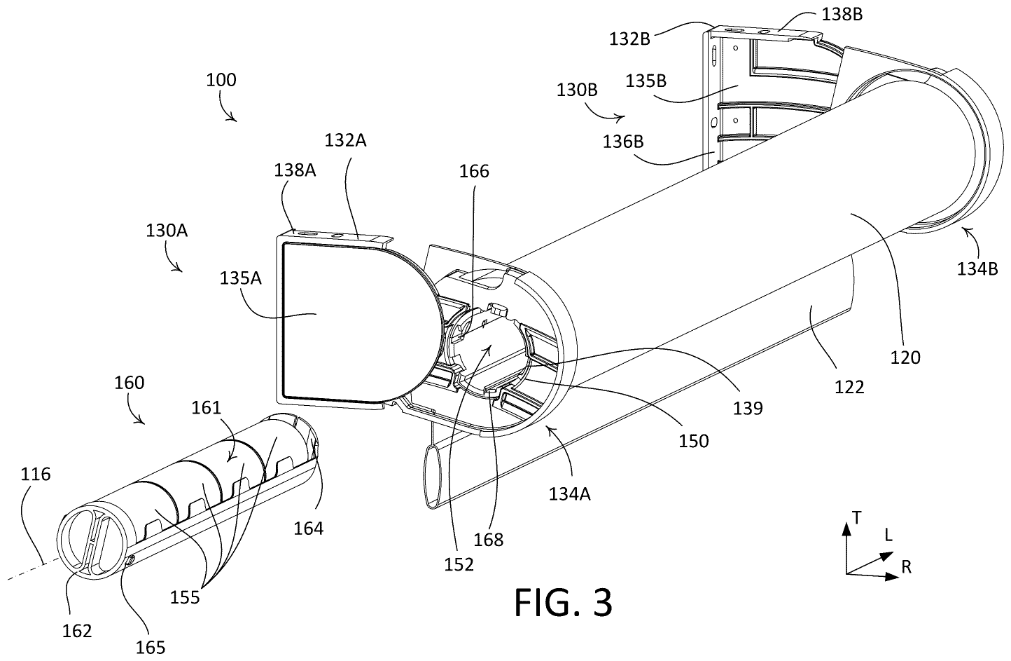

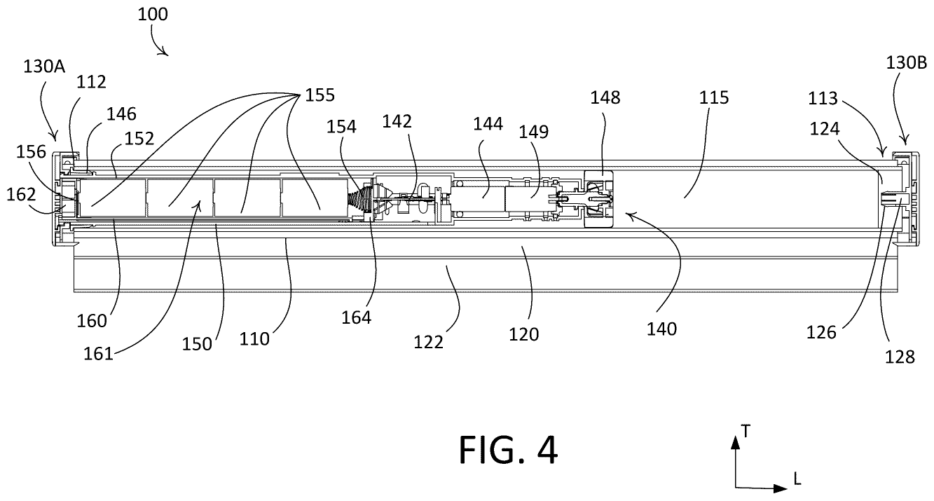

FIG. 1 is a perspective view of an example motorized window treatment 100 (e.g., a battery-powered motorized window treatment system) in an operating position. FIGS. 2 and 3 are perspective views of the example motorized window treatment 100 in an extended position. FIG. 4 is a front cross-section view of the example motorized window treatment 100. The motorized window treatment 100 may include a window treatment assembly 110 and one or more mounting brackets 130A, 130B. The window treatment assembly 110 may comprise a roller tube 111, a flexible material 120 (e.g., a covering material) windingly attached to the roller tube 111, a motor drive unit 140 installed inside of a first end 112 of the roller tube 111, and an idler 124 (FIG. 4) installed inside of a second end 113 of the roller tube 111. The mounting brackets 130A, 130B may be configured to be coupled to or otherwise mounted to a structure. For example, each of the mounting brackets 130A, 130B may be configured to be mounted to (e.g., attached to) a window frame (e.g., to a head jamb or side jambs of the window frame), a wall, a ceiling, or other structure, such that the motorized window treatment 100 is mounted proximate to an opening (e.g., over the opening or in the opening), such as a window for example. The mounting brackets 130A, 130B may be configured to be mounted to a vertical structure (e.g., wall-mounted to a wall as shown in FIG. 1) and/or mounted to a horizontal structure (e.g., ceiling-mounted to a ceiling). For example, the mounting brackets 130A, 130B may be rotated 90 degrees from what is shown in FIG. 1 when the mounting brackets 130A, 130B are mounted to a horizontal structure.

The roller tube 111 may operate as a rotational element of the motorized window treatment 100. The roller tube 111 may be elongate along a longitudinal direction L and rotatably mounted (e.g., rotatably supported) by the mounting brackets 130A, 130B. For example, the window treatment assembly 110 may be rotatably supported by the mounting brackets 130A, 130B. The roller tube 111 may define a longitudinal axis 116. The longitudinal axis 116 may extend along the longitudinal direction L. The mounting bracket 130A may extend from the structure in a radial direction R, as shown in FIG. 1. It should be appreciated that when the mounting brackets 130A, 130B are ceiling-mounted, the mounting bracket 130A may extend from the structure in a transverse direction T. The radial direction R may be defined as a direction perpendicular to the structure and the longitudinal axis 116. The flexible material 120 may be windingly attached to the roller tube 111, such that rotation of the roller tube 111 causes the flexible material 120 to wind around or unwind from the roller tube 111 along a transverse direction T that extends perpendicular to the longitudinal direction L. For example, rotation of the roller tube 111 may cause the flexible material 120 to move between a raised position (e.g., a fully-raised position or a fully-open position as shown in FIG. 1) and a lowered position (e.g., a fully-lowered position or a fully-closed position) along the transverse direction T.

The flexible material 120 may include a first end (e.g., a top or upper end) that is coupled to the roller tube 111 and a second end (e.g., a bottom or lower end) that is coupled to a bottom bar 122 (e.g., a hembar). The bottom bar 122 may be configured, for example weighted, to cause the flexible material 120 to hang vertically. Rotation of the roller tube 111 may cause the bottom bar 122 to move toward or away from the roller tube 111 between the raised and lowered positions.

The flexible material 120 may be any suitable material, or form any combination of materials. For example, the flexible material 120 may be “scrim,” woven cloth, non-woven material, light-control film, screen, and/or mesh. The motorized window treatment 100 may be any type of window treatment. For example, the motorized window treatment 100 may be a roller shade as illustrated, a soft sheer shade, a drapery, a cellular shade, a Roman shade, or a Venetian blind. As shown, the flexible material 120 may be a material suitable for use as a shade fabric, and may be alternatively referred to as a flexible material. The flexible material 120 is not limited to shade fabric. For example, in accordance with an alternative implementation of the motorized window treatment 100 as a retractable projection screen, the flexible material 120 may be a material suitable for displaying images projected onto the flexible material 120.

The motorized window treatment 100 may include a drive assembly, e.g., such as the motor drive unit 140 (e.g., shown in FIG. 4). The motor drive unit 140 may at least partially be disposed within the roller tube 111 (e.g., in the first end 112 of the roller tube 111). For example, the motor drive unit 140 may be secured within a cavity 115 of the roller tube 111. The motor drive unit 140 may include a control circuit that may include a microprocessor and may be mounted to a printed circuit board 142 (e.g., shown in FIG. 4). The motor drive unit 140 may be operably coupled to the roller tube 111 such that when the motor drive unit 140 is operated, the roller tube 111 rotates. The motor drive unit 140 may be configured to rotate the roller tube 111 of the example motorized window treatment 100 such that the flexible material 120 is operable between the raised position and the lowered position. The motor drive unit 140 may further comprise a communication circuit, such as a wireless communication circuit, that may be mounted to the printed circuit board 142 and may be configured to transmit and receive signals (e.g., wireless signals, such as radio-frequency (RF) signals). The motor drive unit 140 may be configured to rotate the roller tube 111 to control the flexible material 120 between the raised position and the lowered position in response to signals received from a remote control device via the communication circuit. During a configuration procedure (e.g., an association procedure) of the motorized window treatment 100, the motor drive unit 140 may be associated with the remote control device, such that the motor drive unit 140 may be responsive to the wireless signals transmitted by the remote control device.

As shown in FIG. 4, the motor drive unit 140 may comprise a motor 144 that is coupled to a drive coupler 148 via a gear assembly 149. The motor drive unit 140 (e.g., the motor 144) may be operatively coupled to the roller tube 111, for example, via the drive coupler 148. The drive coupler 148 may be an output gear that is driven by the motor 144 and transfers rotation of the motor 144 to the roller tube 111. For example, the drive coupler 148 may define a plurality of grooves about its periphery. An inner surface of the roller tube 111 may be splined (e.g., may define a plurality of splines). The grooves of the drive coupler 148 may be configured to engage respective splines of the roller tube 111 such that rotation of the motor 144 is transferred to the roller tube 111, for example, via the drive coupler 148. The motor drive unit 140 may also comprise a bearing assembly 146, which may be rotatably coupled to the roller tube 111 (e.g., the first end 112 of the roller tube 111) and may support (e.g., rotatably support) the roller tube 111. The motorized window treatment 100 may also comprise the idler 124 disposed within the second end 113 of the roller tube 111 (e.g., as shown in FIG. 4).

The motorized window treatment 100 may be configured to enable access to one or more ends of the window treatment assembly 110 while remaining secured to the mounting brackets 130A, 130B. For example, the motorized window treatment 100 may be adjusted (e.g., pivoted or slid) between the operating position (e.g., as shown in FIG. 1) and the extended position (e.g., as shown in FIGS. 2-3) while secured to the mounting brackets 130A, 130B. The operating position may be defined as a position in which the window treatment assembly 110 is supported by and aligned with both mounting brackets 130A, 130B. The extended position may be defined as a position in which one or more ends of the window treatment assembly 110 are accessible while still attached to the brackets 130A, 130B.

When the motorized window treatment 100 is in the extended position, the one or more ends (e.g., end portions) of the motor drive unit 140 and/or roller tube 111 may be accessed, for example, to replace batteries, adjust one or more settings, make an electrical connection, repair one or more components, and/or the like. One or more of the mounting brackets 130A, 130B may enable an end portion 145 of the motor drive unit 140 to be accessed when the motorized window treatment 100 is in the extended position. Each of the mounting brackets 130A, 130B may include a respective stationary portion 132A, 132B configured to be mounted to the structure and a respective movable portion 134A, 134B (e.g., a pivoting portion) configured to be adjusted (e.g., pivoted or rotated) away from the structure. The stationary portion 132A, 132B of each of the mounting brackets 130A, 130B may comprise respective plates 135A, 135B with first flanges 136A, 136B extending from the tops of the plates 135A, 135B and second flanges 138A, 138B extending from the sides of the plates 135A, 135B. The movable portion 134A of the first mounting bracket 130A may be configured to translate (e.g., pivot or rotate) away from the structure to enable the end portion 145 of the motor drive unit 140 to be accessible. For example, a first portion (e.g., the movable portion 134A, 134B) of one or more of the mounting brackets 130A, 130B may pivot or rotate away from a second portion (e.g., the stationary portion 132A, 132B). For example, the movable portions 134A, 134B of the mounting brackets 130A, 130B may be adjusted with respect to the stationary portions 132A, 132B, for example, to expose the end portion 145 of the motor drive unit 140 and/or the idler 124 disposed in the roller tube 111.

The mounting bracket 130A may be configured to receive and support the end portion 145 of the motor drive unit 140. For example, the movable portion 134A of the mounting bracket 130A may define an opening 139 (FIG. 3) that is configured to receive the end portion of the motor drive unit 140. The mounting bracket 130B may be configured to support the idler 124 of the motorized window treatment 100. The idler 124 may be received in the cavity 115 of the roller tube 111. For example, the movable portion 134B of the mounting bracket 100B may define an idler pin 126 (FIG. 4). The idler pin 126 may be configured to be received within an opening 128 (FIG. 4) in the idler 124 of the window treatment assembly 110, for example, to support the idler 124 in the second end 113 of the roller tube 111. The idler 124 of the motorized window treatment 100 may be configured to rotate about the idler pin 126 of the mounting bracket 130B.

The motorized window treatment 100 may be configured to, for example, pivot between the operating position and the extended position. For example, the motorized window treatment 100 may pivot about a fulcrum that is located below the motorized window treatment 100 (e.g., below the mounting brackets 130A, 130B) in the transverse direction T. Both of the mounting brackets 130A, 130B may be pivoted when the motorized window treatment is in the extended position. In some examples, the movable portions 134A, 134B of both of the mounting brackets 130A, 130B may be configured to slide away from the stationary portions 132A, 132B in the radial direction R (e.g., without pivoting or rotating). In this configuration, both ends of the roller tube 111 may be further from the window and/or the structure when the motorized window treatment 100 is in the extended position than when the motorized window treatment 100 is in the operating position. Stated differently, the motorized window treatment 100 may slide between the operating position and the extended position. When the motorized window treatment 100 is in the extended position, the end portion 145 of the motor drive unit 140 may be exposed (e.g., accessible). The end portion 145 of the motor drive unit 140 may be located proximate to the first end 112 of the roller tube 111. The motor drive unit 140 may be received within a cavity 115 (FIG. 4) of the roller tube 111.

The motorized window treatment 100 may comprise a battery holder 160 that may be received in a cavity 152 (e.g., a battery compartment) of a housing 150 of the motor drive unit 140. FIG. 2 depicts the motorized window treatment 100 in the extended position with the battery holder 160 contained within the housing 150 of the motor drive unit 140 of the motorized window treatment 100. FIG. 3 depicts the motorized window treatment 100 in the extended position with the battery holder 160 removed from the housing 150. The battery holder 160 may be configured to retain one or more batteries 155 for powering the motor drive unit 140. For example, the battery holder 160 may define a compartment 161 (e.g., a battery compartment) that is configured to receive the batteries 155. The battery holder 160 (e.g., the compartment 161) may be configured to keep the batteries 155 fixed in place securely while the batteries 155 are providing power to the motor drive unit 140. The battery holder 160 may include a first collar 162 and a second collar 164 at opposed ends of the battery holder 160. The second collar 164 may be positioned proximate to a far end of the compartment 161 of the battery holder 160. The battery holder 160 may be inserted into the housing 150 of the motor drive unit 140 (e.g., into the cavity 152 of the housing 150). The first collar 162 of the battery holder 160 may be configured to enable the battery holder 160 to be rotated within the housing 150.

The battery holder 160 may be configured to clamp the batteries 155 together (e.g., as shown in FIG. 3) such that the batteries 155 can be removed from the battery-powered motorized window treatment 100 at the same time (e.g., together). The first collar 162 and the second collar 164 may be configured to keep the batteries 155 fixed in place (e.g., prevent longitudinal movement of the batteries 155) within the compartment 161. The battery holder 160 may be configured to create a spring tension to hold the batteries 155 together. The battery holder 160 may include an internal spring 154 (FIG. 4) that is configured to maintain contact between the batteries 155 and an electrical contact 156 (FIG. 4) within the battery holder 160. The internal spring 154 may extend within the compartment 161. For example, the electrical contact 156 may define a positive contact within the compartment 161 and the internal spring 182 may define a negative contact within the compartment 161. Stated differently, the electrical contact 156 may be configured to abut a positive side of the one of the batteries 155 within the compartment 161 and the internal spring 154 may be configured to abut a negative side of one of the batteries 155 within the compartment 161. The internal spring 154 may be configured to be compressed in the longitudinal direction L, for example, toward the second collar 164 when the batteries 155 are received within the compartment 161. The electrical contact 156 may be located on the first collar 162 within the compartment 161. The battery holder 160 (e.g., the internal spring 154 and the electrical contact 156) may be configured to be electrically connected to the printed circuit board 142 of the motor drive unit 140, for example, when the battery holder 160 is installed within the motor drive unit 140.

The battery holder 160 may be configured to be removed (e.g., completely removed as shown in FIG. 3) from the housing 150 of the motor drive unit 140 (e.g., from the cavity 152 of the housing 150). When the battery holder 160 is removed from the housing 150, the batteries 155 may be removed from the compartment 161 of the battery holder 160. Replacement batteries may be installed in the compartment 161 of the battery holder 160 and the battery holder 160 may be installed within the cavity 152 of the housing 150.

The battery holder 160 may be configured to be secured within the housing 150 of the motor drive unit 140 (e.g., with the cavity 152 of the housing 150) of the motor drive unit 140. When the battery holder 160 is installed within the housing 150 (e.g., the cavity 152), the battery holder 160 (e.g., the first collar 162) may be rotated to secure the battery holder 160 within the cavity 152 (e.g., to the housing 150). For example, the battery holder 160 (e.g., the first collar 162) may define one or more tabs (e.g., such as tabs 165 shown in FIG. 3) that are configured to secure the battery holder 160 to/within the housing 150. The tabs 165 may be located about a perimeter of the first collar 162. The housing 150 may define slots 166 that are configured to receive (e.g., captively receive) the tabs 165. Each of the slots 166 may extend partially about the perimeter of the housing 150 such that the tabs 165 can translate (e.g., angularly) therein as the battery holder 160 is rotated. The battery holder 160 (e.g., the first collar 162) may include two tabs 165 that are located approximately 150 degrees from one another and the housing 150 may define two slots 166 that are aligned with the tabs 165. The number of slots 166 in the housing 150 may be equal to the number of tabs 165 on the battery holder 160. For example, the battery holder 160 may be rotated between an unlocked position and a locked position in a circumferential direction (e.g., an angular direction). When in the unlocked position, the tabs 165 may be aligned with openings of the slots 166 such that the battery holder 160 can be removed from the housing 150 (e.g., the cavity 152). Although the battery holder 160 is shown having two tabs 165 and the housing 150 is shown with two slots 166, it should be appreciated that the battery holder 160 may include any number of tabs 165 (e.g., one, two, more than two) and the housing 150 may define any number of slots 166 (e.g., one, two, more than two).

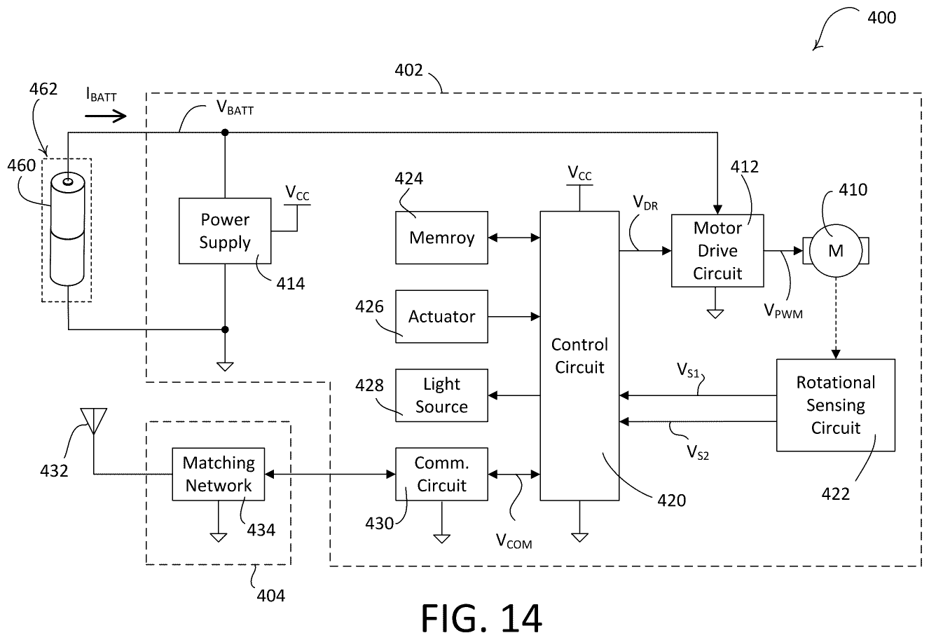

The motor drive unit 140 may include a button 168. For example, the button 168 may be configured to move in the longitudinal direction L in response to a force applied to the button 168. For example, the button 168 may be accessible when the motorized window treatment 100 is in the extended position. The button 168 may be covered by the stationary portion 132A of the first mounting bracket 130A when the motorized window treatment 100 is in the operating position. The button 168 may be configured to actuate a tactile switch (not shown) mounted to the printed circuit board 142 when the button 168 is pressed in the longitudinal direction L. The control circuit mounted to the printed circuit board 142 may be responsive to actuations of the button 168. For example, the control circuit may be configured to cause the control circuit mounted to the printed circuit board 142 to rotate the roller tube 111 and/or change a mode of operation of the motor drive unit 140 in response to an actuation of the button 268. In addition, the control circuit (e.g., such as control circuit 420 shown in FIG. 14) may be configured to enter a configuration mode (e.g., an association mode) in response to an actuation of the button 168. For example, during the configuration procedure of the motorized window treatment 100, the motor drive unit 140 may be associated with a remote control device, such that the control circuit of the motor drive unit 140 may be responsive to the wireless signals transmitted by the remote control device. Further, the motor drive unit 140 may be configured with one or more operational settings (e.g., preset positions between the raised position and the lowered position) during the configuration procedure.

The mounting brackets 130A, 130B may be configured to operate the motorized window treatment 100 between the operating position and the extended position. For example, movable portions 134A, 134B may be configured to operate the motorized window treatment 100 between the operating position and the extended position. The movable portions 134A, 134B may be referred to as sliding portions, rotating portions, and/or movable portions. A portion (e.g., the first collar 162 of the battery holder 160) of the motor drive unit 140 may be accessible when the motorized window treatment 100 is in the extended position. The movable portion 134A, 134B may be aligned with the stationary portion 132A, 132B when the motorized window treatment 100 is in the operating position such that the end portion of the motor drive unit 140 is covered by the stationary portion 132A.

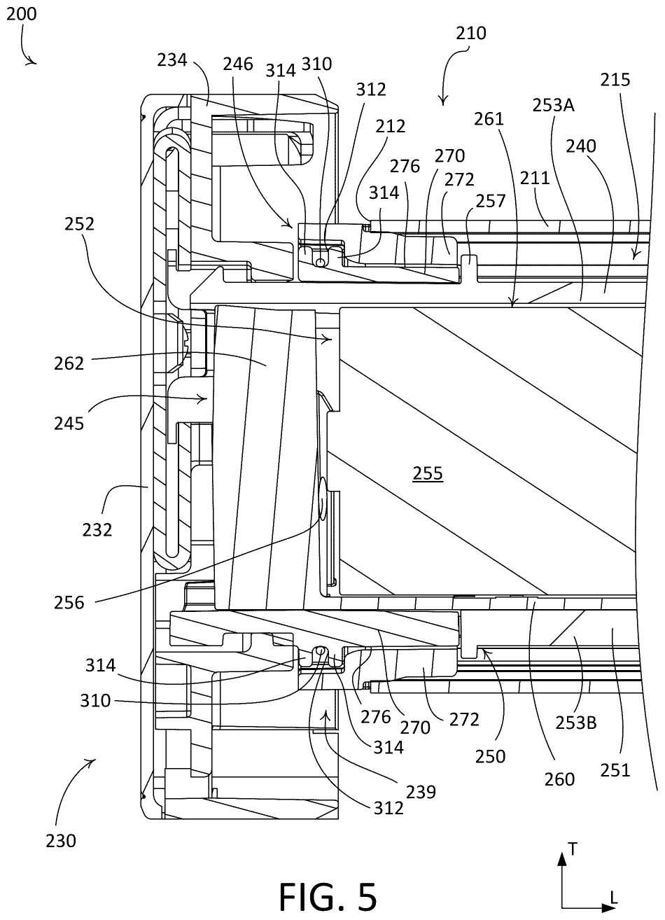

FIG. 5 depicts an example motorized window treatment 200 (e.g., such as the motorized window treatment 100 shown in FIGS. 1-4). FIG. 5 is an enlarged partial front cross-sectional view of the motorized window treatment 200. The motorized window treatment 200 may include a window treatment assembly 210 having a roller tube 211 and a motor drive unit 240. The roller tube 211 may be made from a conductive material, such as aluminum or other suitable metal. The motor drive unit 240 may at least partially be disposed within the roller tube 211 (e.g., in a first end 212 of the roller tube 211). For example, the motor drive unit 240 may be secured within a cavity 215 of the roller tube 211. The motor drive unit 240 may be powered by one or more batteries 255. Although not shown in FIG. 5, the window treatment assembly 210 may also comprise a flexible material windingly attached to the roller tube 211 (e.g., such as the flexible material 120) and an idler (e.g., such as the idler 124 of the motorized window treatment 100). The motorized window treatment 200 may also comprise one or more mounting brackets for mounting the motorized window treatment 200 to a structure, such as a first mounting bracket 230 (e.g., the first mounting bracket 130A) for supporting the motor drive unit 240 and a second mounting bracket (e.g., the second mounting bracket 130B) for supporting the idler. The first mounting bracket 230 and the second mounting bracket may be made from a conductive material, such as aluminum or other suitable metal. In some examples, the first mounting bracket 230 and the second mounting bracket may be made from a non-conductive material, such as plastic.

The motorized window treatment 200 may be adjusted between an operating position (e.g., as shown in FIG. 1) and an extended position (e.g., as shown in FIGS. 2 and 3) while secured to the first mounting bracket 230 and the second mounting bracket. The operating position may be defined as a position in which the window treatment assembly 210 is supported by and aligned with the first mounting bracket 230 and the second mounting bracket (e.g., as shown in FIG. 1). The motorized window treatment 200 may be configured to be operated between the operating position and the extended position, for example, to enable access to replace the batteries 255. The extended position may be defined as a position in which an end portion 245 of the motor drive unit 240 (e.g., received in the first end 212 of the roller tube 211) is accessible while the window treatment assembly 210 is still attached to the first mounting bracket 230, such that the batteries 255 are accessible via the first end 212 of the roller tube 211.

The first mounting bracket 230 and the second mounting bracket may be configured to attach the motorized window treatment 200 to a structure. The first mounting bracket 230 may include a stationary portion 232 (e.g., such as the stationary portion 132A) configured to be mounted to the structure and a movable portion 234 (e.g., such as the movable portion 134A) configured to be adjusted (e.g., pivoted or rotated) away from the structure. The second mounting bracket of the motorized window treatment 200 may have a similar structure as the first mounting bracket 230 and may be a mirror copy of the first mounting bracket 230. The movable portion 234 may be configured to translate the motorized window treatment 200 between the operating position (e.g., as shown in FIG. 1) and the extended position (e.g., as shown in FIGS. 2 and 3). The movable portion 234 may be proximate to the stationary portion 232 when the motorized window treatment 200 is in the operating position and distal from the stationary portion 232 when the motorized window treatment 200 is in the extended position. The first end 212 of the window treatment assembly 210 (e.g., the end portion 245 of the motor drive unit 240) may be accessible (e.g., to replace the batteries 255) when the motorized window treatment 200 is in the extended position.

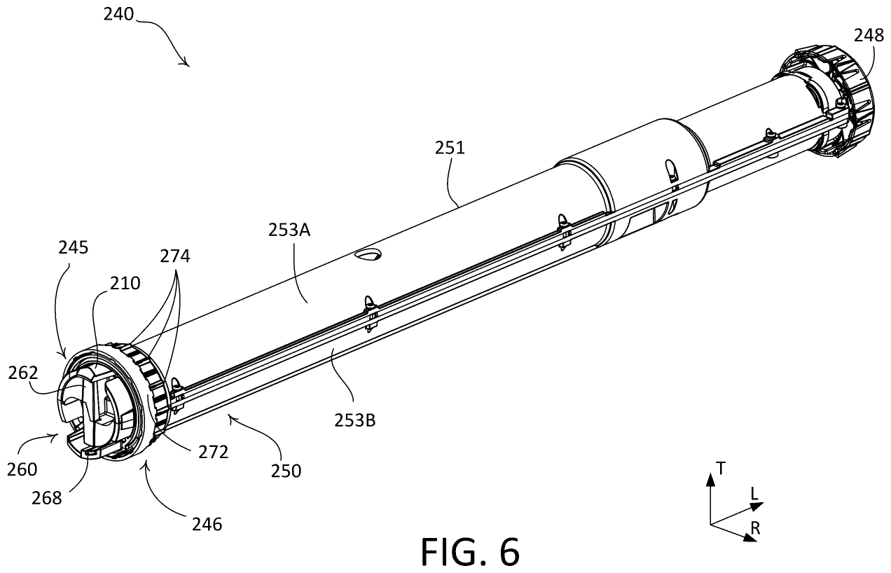

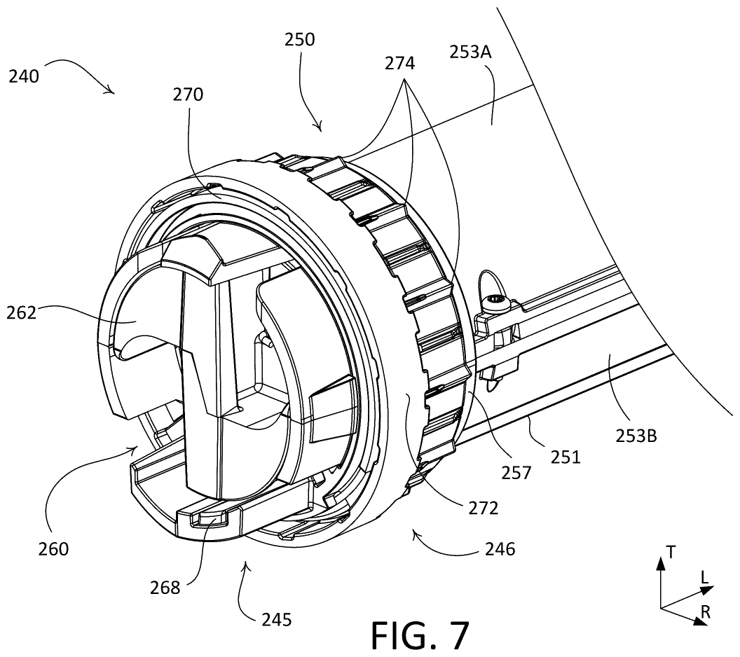

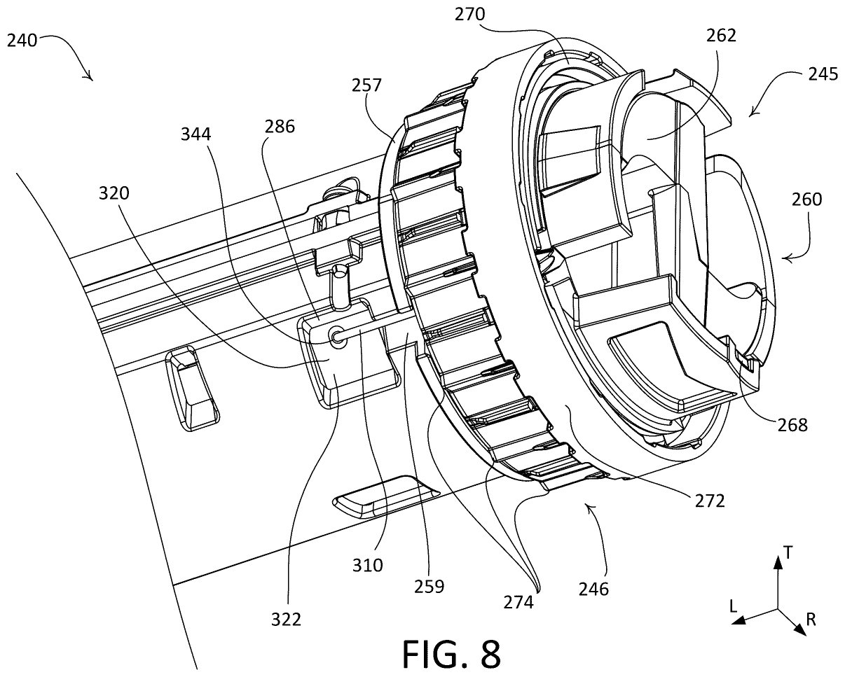

FIG. 6 is a perspective view of the motor drive unit 240. FIG. 7 is an enlarged top perspective view of the end portion 245 of the motor drive unit 240 and FIG. 8 is an enlarged bottom perspective view of the end portion 245 of the motor drive unit 240. The motor drive unit 240 may comprise a housing 250 that may be received in the roller tube 211 (e.g., in the first end 212 of the roller tube 211). The housing 250 may enclose the motor drive unit 240. The housing 250 may comprise a body 251 and a bearing assembly 246. The body 251 may comprise a first portion 253A and a second portion 253B. The bearing assembly 246 may be rotatably coupled to the roller tube 211 (e.g., the first end 212 of the roller tube 211) and may be configured to support (e.g., rotatably support) the roller tube 211. When the housing 250 of the motor drive unit 240 is installed in the roller tube 211, the motor drive unit 240 may be operably coupled to the roller tube 211 via a drive coupler 248, such that when the motor drive unit 240 is operated, the roller tube 211 rotates. The housing 250 may extend between the end portion 245 and the drive coupler 248. The motor drive unit 240 may be configured to rotate the roller tube 211 of the example motorized window treatment 200 such that the flexible material is operable between the raised position and the lowered position.

The motorized window treatment 200 may comprise a battery holder 260 that may be received in a cavity 252 (e.g., a battery compartment) of a housing 250 of the motor drive unit 240 (e.g., formed between the first portion 253A and the second portion 253B of the body 251). The battery holder 260 may be configured to retain one or more batteries 255 for powering the motor drive unit 240. For example, the battery holder 260 may have a similar structure and may operate in a similar manner to retain the batteries 255 as the battery holder 160 shown in FIGS. 3 and 4. For example, the battery holder 260 may define a compartment 261 (e.g., a battery compartment) that is configured to receive the batteries 255. The battery holder 260 (e.g., the compartment 261) may be configured to keep the batteries 255 fixed in place securely while the batteries 255 are providing power to the motor drive unit 240. The battery holder 260 may include a first collar 262 (e.g., the first collar 162) and a second collar (e.g., similar to the second collar 164) at opposed ends of the battery holder 260. The second collar may be positioned proximate to a far end of the compartment 261 of the battery holder 260. The battery holder 260 may be inserted into the housing 250 of the motor drive unit 240 (e.g., into the cavity 252 of the housing 250). The first collar 262 of the battery holder 260 may be configured to enable the battery holder 260 to be rotated within the housing 250.

The battery holder 260 may be configured to clamp the batteries 255 together (e.g., in a similar manner as the battery holder 160 shown in FIG. 3) such that the batteries 255 can be removed from the battery-powered motorized window treatment 200 at the same time (e.g., together). The first collar 262 and the second collar may be configured to keep the batteries 255 fixed in place (e.g., prevent longitudinal movement of the batteries 255) within the compartment 261. The battery holder 260 may be configured to create a spring tension to hold the batteries 255 together. The battery holder 260 may include an internal spring (e.g., such as the internal spring 154 shown in FIG. 4) that is configured to maintain contact between the batteries 255 and an electrical contact 256 (FIG. 5) within the battery holder 260. For example, the electrical contact 256 may define a positive contact within the compartment 261 and the internal spring may define a negative contact within the compartment 261. Stated differently, the electrical contact 256 may be configured to abut a positive side of the one of the batteries 255 within the compartment 261 and the internal spring may be configured to abut a negative side of one of the batteries 255 within the compartment 261. The internal spring may be configured to be compressed in the longitudinal direction L, for example, toward the second collar when the batteries 255 are received within the compartment 261. The electrical contact 256 may be located on the first collar 262 within the compartment 261.

The battery holder 260 may be configured to be removed (e.g., completely removed) from the housing 250 of the motor drive unit 240 (e.g., from the cavity 252 of the housing 250). When the battery holder 260 is removed from the housing 250, the batteries 255 may be removed from the compartment 261 of the battery holder 260. Replacement batteries may be installed in the compartment 261 of the battery holder 260 and the battery holder 260 may be installed within the cavity 252 of the housing 250. The battery holder 260 may be configured to be secured within the housing 250 of the motor drive unit 240 (e.g., within the cavity 252 of the housing 250) of the motor drive unit 140 (e.g., in a similar manner as the battery holder 160 is secured to the housing 150). When the battery holder 260 is installed within the housing 250 (e.g., the cavity 252), the battery holder 260 (e.g., the first collar 262) may be rotated to secure the battery holder 260 within the cavity 252 (e.g., to the housing 250). For example, the battery holder 260 (e.g., the first collar 262) may define one or more tabs (e.g., such as the tabs 165 shown in FIG. 3) that are configured to secure the battery holder 260 to/within the housing 250. In addition, the housing 250 may define, for example, slots (e.g., such as the slots 166 shown in FIG. 3) that are configured to receive (e.g., captively receive) the tabs. For example, the battery holder 260 may be rotated between an unlocked position and a locked position in a circumferential direction (e.g., an angular direction).

As shown in FIG. 5, the bearing assembly 246 may include an inner bearing 270 and an outer bearing 272 that are located external to the roller tube 211. The bearing assembly 246 may be located between the end portion 245 and a rim 257 of the housing 250. The inner bearing 270 and the outer bearing 272 may be non-metallic (e.g., plastic) sleeve bearings. The bearing assembly 246 may be captured between the roller tube 211 and the first mounting bracket 230, such that the bearing assembly 246 may be located in a gap 239 (e.g., longitudinal gap) between the roller tube 211 and the first mounting bracket 230. The components of the motorized window treatment 200 in and/or adjacent to the gap 239 may be non-conductive such that radio-frequency field disruption and/or shielding is minimized. For example, the motorized window treatment 200 may not include conductive (e.g., metal) components in an area radially surrounding the gap 239. The inner bearing 270 may engage the housing 250 of the motor drive unit 240. The inner bearing 270 may be operatively coupled to the housing 250 (e.g., via a press fit connection).

The outer bearing 272 may engage the roller tube 211. The outer bearing 272 may be operatively coupled to the roller tube 211. The outer bearing 272 may rotate with the roller tube 211. The outer bearing 272 may be press fit into engagement with the roller tube 211. For example, the outer bearing 272 may comprise a plurality of splines 274 that are configured to engage corresponding grooves (not shown) of the roller tube 211. The inner bearing 270 may remain stationary with the housing 250 as the roller tube 211 rotates. Stated differently, the roller tube 211 and the outer bearing 272 may rotate about the inner bearing 270 and the housing 250 of the motor drive unit 240. The outer bearing 272 may be configured to slide on an outer surface 276 of the inner bearing 270. The battery holder 260 may be configured to be electrically connected to the motor drive printed circuit board 242 of the motor drive unit 240, for example, when the battery holder 260 is installed within the motor drive unit 240.

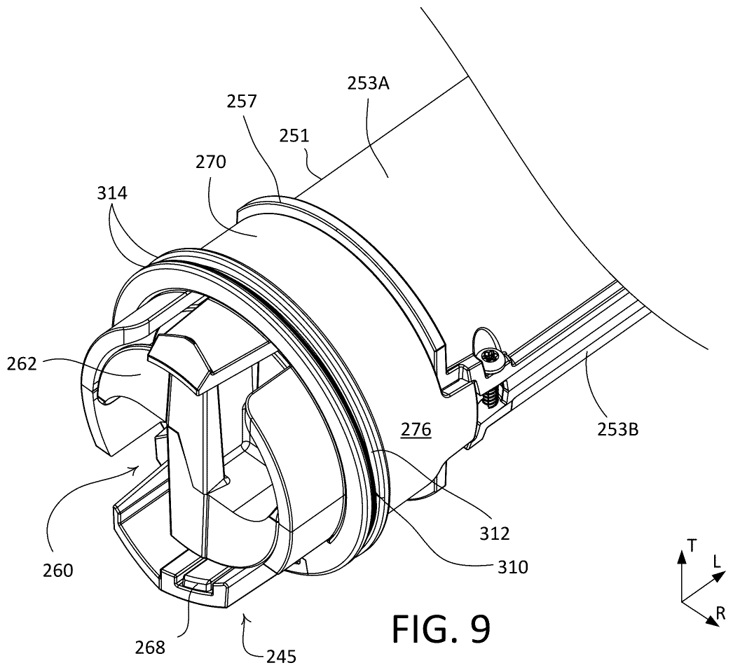

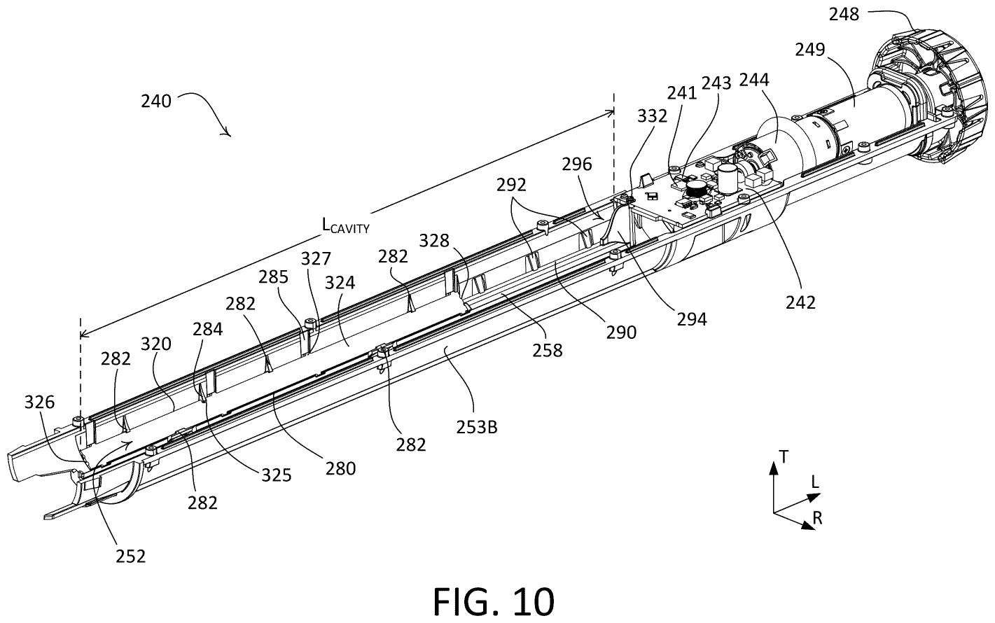

FIG. 9 is an enlarged top perspective view of the motor drive unit 240 with the outer bearing 272 of the bearing assembly 246 removed. FIG. 10 is a perspective view of the motor drive unit 240 with the first portion 253A of the body 251 of the housing 250 and the battery holder 260 removed. The motor drive unit 240 may comprise a first printed circuit board, such as a motor drive printed circuit board 242 on which a control circuit 241 (e.g., a microprocessor) for the motor drive unit 240 may be mounted. The motor drive unit 240 may further comprise a motor 244 that is coupled to the drive coupler 248 via a gear assembly 249. The drive coupler 248 may be an output gear that is driven by the motor 244 and transfers rotation of the motor 244 to the roller tube 211. For example, the drive coupler 248 may be configured to engage with an inner surface of the roller tube 211 such that rotation of the motor 244 is transferred to the roller tube 211, for example, via the drive coupler 248. The motor drive unit 240 may also comprise a communication circuit (e.g., such as communication circuit 425 shown in FIG. 14), such as a wireless communication circuit 243, that may be mounted to the motor drive printed circuit board 242 and may be configured to transmit and receive signals (e.g., wireless signals, such as radio-frequency (RF) signals) at a communication frequency f_{COMM} (e.g., approximately 434 MHz). The control circuit 241 of the motor drive unit 240 may be configured to rotate the roller tube 211 to control the flexible material between the raised position and the lowered position in response to signals received from a remote control device via the wireless communication circuit 243. The motor drive printed circuit board 242 may be configured to be electrically connected to the battery holder 260 (e.g., the batteries 255 installed in the battery holder 260) when the battery holder 260 is installed within the cavity 252 of the housing 250 of the motor drive unit 240 (e.g., for powering the control circuit 241, the wireless communication circuit 243, and/or other low-voltage circuitry of the motor drive unit 240). As shown in FIG. 10, the cavity 252 may extend for a length L_{CAVITY} (e.g., approximately 12 inches), such that the battery holder 260 may be sized to hold a predetermined number of (e.g., four) D-cell batteries.

As shown in FIGS. 6-8, the motor drive unit 240 may include a button 268. For example, the button 268 may be configured to move in the longitudinal direction L in response to a force applied to the button 268. For example, the button 268 may be accessible when the motorized window treatment 200 is in the extended position. The button 268 may be covered by the stationary portion 232 of the first mounting bracket 230 when the motorized window treatment 200 is in the operating position. The button 268 may be attached to an actuation member (not shown) that extends for the length L_{CAVITY} of the cavity 252 from the end portion 245 to the motor drive printed circuit board 242. The actuation member may extend through a channel (not shown) in an inner surface 258 of the housing 250 for the length L_{CAVITY} of the cavity 252. The button 268 (e.g., the actuation member) may be configured to actuate a tactile switch (not shown) mounted to the motor drive printed circuit board 242 when the button 268 is pressed in the longitudinal direction L. The control circuit mounted to the motor drive printed circuit board 242 may be responsive to actuations of the button 268. For example, the control circuit may be configured to cause the control circuit mounted to the motor drive printed circuit board 242 to rotate the roller tube 211 and/or change a mode of operation of the motor drive unit 240 in response to an actuation of the button 268. In addition, the control circuit may be configured to enter a configuration mode (e.g., an association mode) in response to an actuation of the button 268. For example, during the configuration procedure of the motorized window treatment 200, the motor drive unit 240 may be associated with a remote control device, such that the control circuit of the motor drive unit 240 may be responsive to the wireless signals transmitted by the remote control device. Further, the motor drive unit 240 may be configured with one or more operational settings (e.g., preset positions between the raised position and the lowered position) during the configuration procedure.

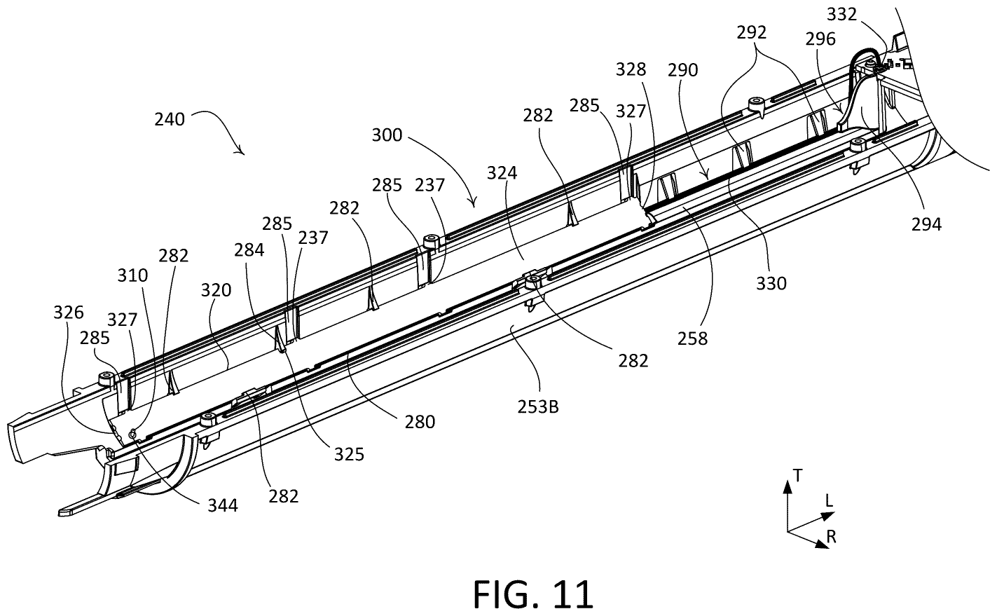

FIG. 11 is an enlarged partial perspective view of the motor drive unit 240 with the first portion 253A of the body 251 of the housing 250 and the battery holder 260 removed. The motor drive unit 240 may further comprise an antenna system 300 including an antenna element 310 (e.g., an antenna wire), a second printed circuit board, such as an antenna-system printed circuit board 320, and a cable, such as a coaxial cable 330. The antenna system 300 may be electrically coupled to the wireless communication circuit 243 mounted to the motor drive printed circuit board 242 for allowing the wireless communication circuit 243 to transmit and receive the wireless signals (e.g., at the communication frequency f_{COMM}). For example, the antenna element 310 may comprise an insulated electrical conductor, such as a 22-gauge electrical wire (e.g., a solid or stranded electrical wire) with a polyvinyl chloride (PVC) coating.

As shown in FIG. 9, the antenna element 310 may be located adjacent to the end portion 245 of the motor drive unit 240. The antenna system 300 may extend for the length L_{CAVITY} from the end portion 245 of the motor drive unit 240 to the motor drive printed circuit board 242. For example, the antenna element 310 may be wrapped around (e.g., wound about) the housing 250 (e.g., around the body 251 and/or the bearing assembly 246 of the housing 250) adjacent to the first end 212 of the roller tube 211. For example, the antenna element 310 may be wrapped around the housing 250 of the motor drive unit 240 within the bearing assembly 246. The antenna element 310 may be located in one or more channels, such as a peripheral (e.g., circumferential) channel 312, in the housing 250 of the motor drive unit 240 (e.g., as shown in FIGS. 5 and 9). For example, the peripheral channel 312 may be formed on the outer surface 276 of the inner bearing 270 of the bearing assembly 246. The peripheral channel 312 may be formed by walls 314 that extend from the outer surface 276 of the inner bearing 270. The walls 314 may extend circumferentially about the outer surface 276 of the inner bearing 270. For example, the peripheral channel 312 may be defined between the respective walls 314. When the bearing assembly 246 is installed on the housing 250, the outer bearing 272 may be positioned between the walls 314 that form the peripheral channel 312 and the rim 257 of the housing 250, such that the outer bearing 272 is configured to slide across the outer surface 276 of the inner bearing 270. In some examples, the peripheral channel 312 may extend into the inner bearing 270 (e.g., may extend past the outer surface 276). In addition, the antenna element 310 may be located internal to the inner bearing 270 of the bearing assembly 246 (e.g., extending through one or more tunnels in the inner bearing 270). For example, the antenna element 310 may be at least partially wrapped around the housing 250 (e.g., around the inner bearing 270 of the bearing assembly 246). In some examples, the antenna element 310 may be replaced by an electrical conductor (e.g., an electrical trace) formed on a flexible material, such as a flexible printed circuit board, which may extend from the antenna-system printed circuit board 320 and may wrap around the housing 250 within the bearing assembly 246.

The antenna element 310 may be wrapped around the housing 250 of the motor drive unit 240 (e.g., within the bearing assembly 246), such that the antenna element 310 is located within an area that surrounds the circumference of the motor drive unit 240 and falls within an area defined by the bearing assembly 246. The antenna element 310 may be wrapped around the motor drive unit 240 adjacent to the gap 239 between the roller tube 211 and the first mounting bracket 230 (e.g., lie at least partially within an area defined by the gap). For example, the antenna element 310 may be aligned with the gap 239. The antenna system 300 (e.g., the antenna element 310) may transmit and/or receive RF signals through the gap 239. In addition, when the antenna element 310 is emitting electromagnetic waves, the electromagnetic waves may be coupled to the roller tube 211 (e.g., capacitively coupled to the roller tube), which may result in current flow (e.g., standing waves) on the surface of the roller tube 211 (e.g., since the roller tube 211 is made from a conductive material). As a result, the roller tube 211 may re-radiate the electromagnetic waves emitted by the antenna element 310, which may increase the amount of RF signals transmitted and/or received by the antenna system 300.

While the antenna element 310 is shown in FIGS. 5 and 9 as being partially wrapped around the motor drive unit 240 (e.g., within the bearing assembly 246), it should be appreciated that the antenna element 310 may be wrapped around the motor drive unit 240 in other manners and/or shapes. For example, the motor drive unit 240 may comprise a peripheral channel formed on the body 251 of the housing 250 (e.g., on an outer surface of the first and second portions 253A, 253B of the body 251) and/or may extend into the body 251 of the housing 250, for example, as shown and described in commonly-assigned U.S. Patent Application Publication No. 2022/0381085, published Dec. 1, 2022, entitled ANTENNA FOR A MOTORIZED WINDOW TREATMENT, the entire disclosure of which is hereby incorporated by reference. Additionally or alternatively, the one or more channels in which the antenna element 310 is located may be formed on an inner surface of the first portion 253A of the body 251 of the housing 250 and the inner surface 258 of the second portion 253B of the body 251 of the housing 250. The antenna element 310 may be located internal to the housing 250 of the motor drive unit 240 (e.g., extending through one or more tunnels in the housing 250). Further, rather than only partially wrapping around the housing 250 of the motor drive unit 240, the antenna element 310 may wrap around the motor drive unit 240 multiple times. For example, the motor drive unit 240 may comprise multiple channels in parallel and/or a single channel formed in a helix shape in the inner bearing 270 and/or the housing 250 of the motor drive unit 240, such that the antenna element 310 wraps around the housing 250 multiple times (e.g., as also described in previously referenced U.S. Patent Application Publication No. 2022/0381085).

As shown in FIG. 11, the antenna-system printed circuit board 320 may be mounted to the housing 250. For example, the antenna-system printed circuit board 320 may be received in a recess 280 in the inner surface 258 of the second portion 253B of the body 251 of the housing 250. When the antenna-system printed circuit board 320 is received in the recess 280, the cavity 252 may be defined by the inner surface 258 of the second portion 253B of the body 251 and the rear side 324 of the antenna-system printed circuit board 320. The antenna-system printed circuit board 320 may be configured to allow the wireless communication circuit 243 mounted to the motor drive printed circuit board 242 to be in electrical communication with the antenna element 310 (e.g., the wireless communication circuit 243 may be electrically coupled to the antenna element 310 via the antenna-system printed circuit board 320).

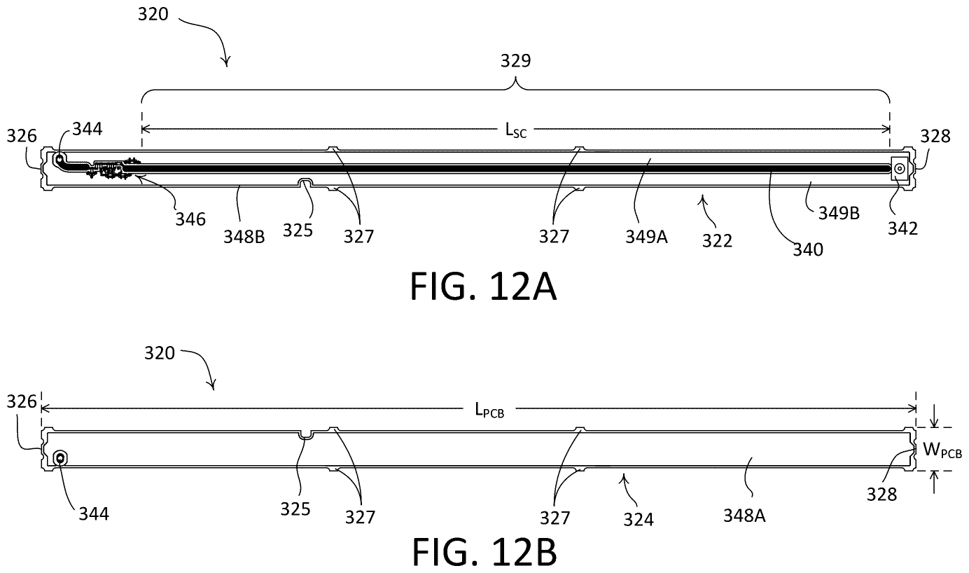

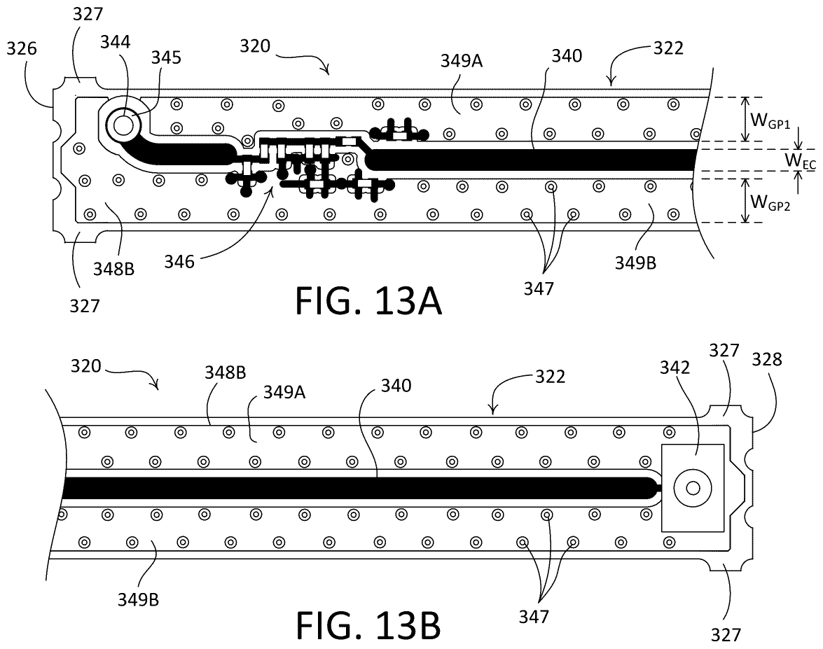

FIG. 12A is a front view of the antenna-system printed circuit board 320 showing a front side 322 (e.g., a front surface) of the antenna-system printed circuit board 320. FIG. 12B is a rear view of the antenna-system printed circuit board 320 showing a rear side 324 (e.g., a rear surface) of the antenna-system printed circuit board 320. The antenna-system printed circuit board 320 may extend from a first end 326 to a second end 328. FIG. 13A is a partial front view showing the first end 326 of the antenna-system printed circuit board 320 and FIG. 13B is a partial front view showing the second end 328 of the antenna-system printed circuit board 320. For example, the antenna-system printed circuit board 320 may be made of a rigid material (e.g., a substrate such as an FR-4 material). The antenna-system printed circuit board 320 may comprise, for example, a multi-layer printed circuit board. The antenna-system printed circuit board 320 may have a length L_{PCB} of approximately 8.5 inches and a width W_{PCB} of approximately 0.36 inches. The antenna-system printed circuit board 320 may have an area A_{PCB} of approximately 3 square-inches. The antenna-system printed circuit board 320 may extend for more than half of the length L_{CAVITY} of the cavity 252 of the housing 250 (e.g., the length L_{PCB} of the antenna-system printed circuit board 320 may be greater than half of the length L_{CAVITY} of the cavity 252 of the housing 250). For example, the length L_{PCB} of the antenna-system printed circuit board 320 may be approximately 70% of the length L_{CAVITY} of the cavity 252 of the housing 250. The length L_{PCB} of the antenna-system printed circuit board 320 and the length L_{CAVITY} of the cavity 252 of the housing 250 may be adjusted depending upon the specific structure of the motor drive unit 240 and/or the number and/or type of batteries received in the cavity 252 of the housing 250.

The antenna-system printed circuit board 320 may be positioned in the recess 280 such that the first end 326 is located towards the antenna element 310 (e.g., towards the end portion 245 of the housing 250) and the second end 328 is located towards the motor drive printed circuit board 242. In addition, the antenna-system printed circuit board 320 may be positioned in the recess 280 such that the front side 322 is located towards the inner surface 258 of the second portion 253B of the body 251 of the housing 250 and the rear side 324 is located towards the cavity 252 of the housing 250 (e.g., and towards the inner surface of the first portion 253A of the body 251 of the housing 250). The antenna-system printed circuit board 320 may be held within the recess 280 by a plurality of snaps 282 that extend from the inner surface 258 of the second portion 253B of the body 251 of the housing 250. The snaps 282 may engage outer edges of the antenna-system printed circuit board 320. For example, the snaps 282 may be configured to secure the antenna-system printed circuit board 320 to the housing 250 (e.g., within the recess 280). When installed in the recess 280, the antenna-system printed circuit board 320 may be oriented at an angle (e.g., with respect to transverse direction T and/or the radial direction R). The antenna-system printed circuit board 320 may comprise a notch 325 configured to receive (e.g., engage) a projection 284 that extends from the inner surface 258 of the second portion 253B of the body 251 of the housing 250. The antenna-system printed circuit board 320 may comprise a tabs 327 configured to be received in (e.g., engage) respective notches 285 in the inner surface 258 of the second portion 253B of the body 251 of the housing 250. The engagement between the projection 284 and the notch 325 in the antenna-system printed circuit board 320 and the engagement between the tabs 327 of the antenna-system printed circuit board 320 and the respective notches 285 in the inner surface 258 of the second portion 253B of the body 251 of the housing 250 may help to prevent movement of the antenna-system printed circuit board 320 in the longitudinal direction L of the motorized window treatment 200. For example, the projection 284 and the notch 325 may be configured to secure the antenna-system printed circuit board 320 in position along the longitudinal direction L. In addition, the tabs 327 and the respective notches 285 may be configured to secure the antenna-system printed circuit board 320 in position along the longitudinal direction L.

The antenna-system printed circuit board 320 may comprise an electrical conductor 340 (e.g., a transmission line) that extends from the second end 328 towards the first end 326 of the antenna-system printed circuit board 320. The electrical conductor 340 may be configured to couple the antenna element 310 to the wireless communication circuit 243. For example, the electrical conductor 340 may enable electrical communication between the antenna element 310 and the wireless communication circuit 243. The motor drive unit 240 may also comprise a first connector 342 (e.g., a first coaxial-cable connector) mounted to the front side 322 of the antenna-system printed circuit board 320 adjacent to the second end 328 of the antenna-system printed circuit boards 320. The first connector 342 may be configured to couple the antenna-system printed circuit board 320 to the motor drive printed circuit board 242. The first connector 342 may be pointed towards the inner surface 258 of the second portion 253B of the body 251 of the housing 250 when the antenna-system printed circuit board 320 is received in the recess 280.

The antenna element 310 may terminate at the antenna-system printed circuit board 320. The antenna-system printed circuit board 320 may comprise a through-hole 344 located near the first end 326 of the antenna-system printed circuit board 320. The antenna element 310 may extend through the through-hole 344 and be soldered to an electrical pad 345 surrounding through-hole 344. The antenna element 310 may be electrically connected to the first connector 342 on the antenna-system printed circuit board 320. As shown in FIG. 8, the antenna element 310 may extend from the bearing assembly 246 (e.g., from the peripheral channel 312 formed on the walls 314 on the outer surface 276 of the inner bearing 270) and through a notch 259 in the rim 257 of the housing 250. The antenna element 310 may then extend through an opening 286 in the housing 250 to the through-hole 344 in the antenna-system printed circuit board 320.

The motor drive unit 240 may also comprise a matching network circuit 346 mounted to the antenna-system printed circuit board 320. The matching network circuit 346 may be in electrical communication with (e.g., electrically coupled between) the antenna element 310 and the wireless communication circuit 243 mounted to the motor drive printed circuit board 242. The matching network circuit 346 may be in electrical communication (e.g., electrically coupled in series) with the electrical conductor 340, for example, between the first connector 342 and the through-hole 344. The matching network circuit 346 may be located towards the first end 326 of the antenna-system printed circuit board 320 to be near the antenna element 310. The matching network circuit 346 may be configured to optimize the performance of the antenna system 300. For example, the matching network circuit 346 may be configured to match an impedance of the antenna element 310 to an impedance of the wireless communication circuit 243 to obtain a maximum transfer of power between the antenna element 310 and the wireless communication circuit 243. The matching network circuit 346 may comprise one or more inductors and/or one or more capacitors. For example, the matching network circuit 346 may include, for example, an inductor-capacitor matching network, such as an inductor-capacitor (LC) filter circuit.

The coaxial cable 330 may allow the antenna-system printed circuit board 320 to be in electrical communication with the motor drive printed circuit board 242 (e.g., the antenna-system printed circuit board 320 may be electrically coupled to the motor drive printed circuit board 242 via the coaxial cable 330). The motor drive unit 240 may comprise a second connector 332 (e.g., a second coaxial-cable connector) mounted to the motor drive printed circuit board 242. The coaxial cable 330 may be connected between the first connector 342 on the on the antenna-system printed circuit board 320 and the second connector 332 on the motor drive printed circuit board 242. For example, the coaxial cable 330 may extend through a coaxial cable channel 290 in the inner surface 258 of the second portion 253B of the body 251 of the housing 250. The coaxial cable channel 290 may extend in the longitudinal direction L of the motorized window treatment 200. The coaxial cable 330 may extend through the coaxial cable channel 290 between the recess 280 (e.g., in which the antenna-system printed circuit board 320 is located) and the motor drive printed circuit board 242. The coaxial cable 330 may be held in the coaxial cable channel 290 by one or more tabs 292 that extend from the inner surface 258 of the second portion 253B of the body 251 of the housing 250. Although the figures show the antenna-system printed circuit board 320 connected to the motor drive printed circuit board 242 via the coaxial cable 330, it should be appreciated that another type of cable (e.g., such as a ribbon cable, an ethernet cable, a fiber-optic cable, etc.) may be used to connect the antenna-system printed circuit board 320 to the motor drive printed circuit board. In some examples, the wireless communication circuit 243 may be mounted to the antenna-system printed circuit board 320 and the wireless communication circuit 243 may be coupled to the circuitry on the motor drive printed circuit board 242 via a cable, such as a ribbon cable.

The motor drive unit 240 may further comprise a fin 294 extending from the inner surface 258 of the second portion 253B of the body 251 of the housing 250. For example, the fin 294 may form a pocket 296 (e.g., compartment) between the fin 294 and the inner surface 258 of the second portion 253B of the body 251 of the housing 250. The pocket 296 may be configured to receive the coaxial cable 330. For example, the fin 294 may be a protrusion that defines the pocket 296. The coaxial cable 330 may extend through the pocket 296 as the coaxial cable 330 bends between the coaxial cable channel 290 and the second connector 332 on the motor drive printed circuit board 242. The fin 294 may prevent the coaxial cable 330 from bending into the cavity 252 of the housing 250 and interfering with the battery holder 260 when the battery holder 260 is installed in the cavity 252 of the housing 250. Although the fin 294 is shown in the figures with a specific sloped geometric shape, it should be appreciated that the fin 294 could define alternate geometry.

The electrical conductor 340 may extend from the first connector 342 at the second end 328 towards the antenna element 310 at the first end 326 of the antenna-system printed circuit board 320. The electrical conductor 340 may extend down the middle of the antenna-system printed circuit board 320. For example, the electrical conductor 340 may be located proximate to a center of the antenna-system printed circuit board 320 (e.g., as shown in FIG. 13A). For example, the electrical conductor 340 may be characterized by a width WEC (e.g., approximately 0.05 inches).

The antenna-system printed circuit board 320 may comprise one or more ground planes, which may operate as a counterpoise for the antenna element 310 (e.g., such that the antenna element 310 operates as a dipole antenna). For example, the antenna-system printed circuit board 320 may comprise a first ground plane 348A (e.g., a planar piece of conductive material, such as copper) on the rear side 324 of the antenna-system printed circuit board 320. As shown in FIG. 13B, the first ground plane 348A may fill approximately the area A_{PCB} (e.g., the entire area) of the antenna-system printed circuit board 320 (e.g., the first ground plane 348A may have an area of approximately 3 square-inches on the rear side 324 of the antenna-system printed circuit boards 320). In addition, the antenna-system printed circuit board 320 may comprise a second ground plane 348B (e.g., a planar piece of conductive material, such as copper) on the front side 322 of the antenna-system printed circuit board 320. As shown in FIG. 13A, the electrical conductor 340 may bisect the second ground plane 348B on the front side 322 of the antenna-system printed circuit board 320, such that the second ground plane 348B has a first portion 349A on one side (e.g., a first side, above, etc.) of the antenna-system printed circuit board 320 and a second portion 349B on the other side (e.g., a second side, below, etc.) of the antenna-system printed circuit board 320. The first portion 349A of the second ground plane 348B on the front side 322 of the antenna-system printed circuit board 320 may be characterized by a width W_{GP1}, and the second portion 349B of the second ground plane 348B on the front side 322 of the antenna-system printed circuit board 320 may each characterized by a width W_{GP2}. For example, the width W_{GP1} of the first portion 349A of the second ground plane 348B and the width W_{GP2} of the second portion 349B of the second ground plane 348B may be approximately the same (e.g., approximately 0.1 inches). A plurality of vias 347 may be configured to allow the second ground plane 348B on the front side 322 of the antenna-system printed circuit board 320 (e.g., the first portion 349A and the second portion 349B) to be in electrical communication with the first ground plane 348A on the rear side 324 of the antenna-system printed circuit board 320 (e.g., the second ground plane 348B may be electrically coupled to the first ground plane 348A via the plurality of vias 347). Each of the vias 347 may extend between the front side 322 and the rear side 324 of the antenna-system printed circuit board 320. The first and second ground planes 348A, 348B may be in electrical communication with (e.g., electrically coupled to) a circuit common of the motor drive printed circuit board 242 (e.g., a circuit common of the wireless communication circuit 243), such that the first and second ground planes 348A, 348B operate as the counterpoise of the antenna element 310.

The antenna-system printed circuit board 320 may provide rigid support of first and second ground planes 348A, 348B close to the through-hole 344 to which the antenna element 310 is electrically connected, such that the antenna-system printed circuit board 320 provides for rigid support of the counterpoise of the antenna element 310 close to the antenna element 310. the antenna-system printed circuit board 320 may be configured to resist (e.g., prevent) deformation of the counterpoise of the antenna element (e.g., close to the antenna element 310). For example, the antenna-system printed circuit board 320 may provide a rigidity (e.g., rigid support of the first and second ground planes 348A, 348B) that is greater than that of a coaxial cable (e.g., such as the coaxial cable 330). The coaxial cable 330 may be susceptible to movements in location and/or orientation during shipment and/or operation of the motor drive unit 240, which may lead to degradation and/or inconsistencies in the operation of the antenna system 300 if the counterpoise is not rigidly supported. Because the first and second ground planes 348A, 348B occupy a large amount of the surface areas of the front side 322 and the rear side 324 of the antenna-system printed circuit board 320, the first and second ground planes 348A, 348B may operate to shield the antenna element 310 from variations in the location and/or orientation of the coaxial cable 330. The antenna element 310 may be directly connected to the antenna-system printed circuit board 320, which includes the matching network circuit 346 and the ground planes 348A, 348B, with no other element, such as cables between the antenna element 310 and the matching network circuit 346 or ground planes 348A, 348B.

As shown in FIG. 12A, the antenna-system printed circuit board 320 may comprise a transmission line portion 329 (e.g., a shielded-conductor portion) that extends from the first connector 342 to the matching network circuit 346. The transmission line portion 329 may comprise the electrical conductor 340 with the first and second portions 349A, 349B of the second ground plane 348B on each side of the electrical conductor 340 on the front side 322 of the antenna-system printed circuit board 320. The transmission line portion 329 may also comprise the first ground plane 348A on the rear side 324 of the antenna-system printed circuit boards 320. The transmission line portion 329 may comprise, for example, a microstrip or a coplanar waveguide. For example, the transmission line portion 329 of the antenna-system printed circuit board 320 may extend for a length L_{SC} (e.g., approximately 7.5 inches). The transmission line portion 329 of the antenna-system printed circuit board 320 may extend for more than half of the length L_{CAVITY} of the cavity 252 of the housing 250 (e.g., the length L_{SC} of the transmission line portion 329 may be greater than half of the length L_{CAVITY} of the cavity 252 of the housing 250). For example, the length L_{SC} of the transmission line portion 329 of the antenna-system printed circuit board 320 may be approximately 63% of the length L_{CAVITY} of the cavity 252 of the housing 250. In addition, the transmission line portion 329 may extend for most of the length L_{PCB} of the antenna-system printed circuit board 320 (e.g., the length L_{SC} of the transmission line portion 329 may be approximately 88% of the length of the length L_{PCB} of the antenna-system printed circuit board 320.

The transmission line portion 329 of the antenna-system printed circuit board 320 may mimic the structure of a coaxial cable (e.g., such as the coaxial cable 330). Rather than having the first connector 342 located near the matching network circuit 346 (e.g., near the first end 326 of the antenna-system printed circuit board 320) and having the coaxial cable 330 extending between the motor drive printed circuit board 242 and the matching network circuit 346, the transmission line portion 329 of the antenna-system printed circuit board 320 (e.g., the electrical conductor 340 and the first and second ground planes 348A, 348B) may extend for much of the length L_{CAVITY} of the cavity 252 (e.g., greater than half of the length L_{CAVITY} of the cavity 252) between the matching network circuit 346 and the motor drive printed circuit board 242. Since the antenna-system printed circuit board 320 is made of a rigid material, the transmission line portion 329 of the antenna-system printed circuit board 320 may be less susceptible to movements in location and/or orientation during shipment and/or operation of the motor drive unit 240 (e.g., the transmission line portion 329 may provide a rigid coaxial cable structure that extends for much of the length L_{CAVITY} of the cavity 252 between the matching network circuit 346 and the motor drive printed circuit board 242).

While the antenna-system printed circuit board 320 is described as being a made of a rigid material, the antenna-system printed circuit board 320 could be made of other material and/or take other forms. For example, the antenna-system printed circuit board 320 may comprise a flexible printed circuit board on which the electrical conductor 340, the first ground plane 348A, and the second ground plane 348B. In addition, the transmission line portion 329 of the antenna-system printed circuit board 320 may also be formed through a laser direct structuring (LDS) process through which conductive material (e.g., the electrical conductor 340, the first ground plane 348A, and the second ground plane 348B) are deposited on a rigid material other than a printed circuit board substrate (e.g., such a plastic).

FIG. 14 is a block diagram of an example motor drive unit 400 (e.g., the motor drive unit 140 shown in FIG. 4 and/or the motor drive unit 240 shown in FIGS. 5-9) of a motorized window treatment (e.g., such as the motorized window treatment 100 shown in FIGS. 1-2 and/or the motorized window treatment 200 shown in FIG. 5). The motor drive unit 400 may comprise a motor 410 (e.g., a direct-current motor) that may be coupled for raising and lowering a flexible material (e.g., the flexible material 120). For example, the motor 410 may be coupled to a roller tube (e.g., roller tube 111 shown in FIGS. 1-4 and/or the roller tube 211 shown in FIG. 5) of the motorized window treatment for rotating the roller tube for raising and lowering a flexible material (e.g., a shade fabric). Rotation of the roller tube may be configured to raise and lower the flexible material.

The motor drive unit 400 may comprise a motor drive PCB circuit 402 (e.g., which may be mounted to the motor drive printed circuit board 242 and an antenna-system PCB circuit 404 (e.g., which may be mounted to the antenna-system printed circuit board 320). The motor drive unit 400 may comprise a battery holder 462 (e.g., which may be an example of the battery holder 160 of the motorized window treatment 100 shown in FIGS. 3-4 and/or the battery holder 260 of the motorized window treatment 200 shown in FIG. 5) that is configured to receive a DC power source. The DC power source may be, for example, one or more batteries 460. In this example, the battery holder 462 may be configured to receive one or more batteries 460 (e.g., four “D” batteries), such as the batteries 155 of FIG. 4 and/or the batteries 255 shown in FIG. 5. The batteries 460 may provide a battery voltage VBATT to the motor drive unit 400. In addition, alternate DC power sources, such as a solar cell (e.g., a photovoltaic cell), an ultrasonic energy source, and/or a radio-frequency (RF) energy source, may be coupled in parallel with the one or more batteries 460, or in some examples be used as an alternative to the batteries 460. Further, an external DC power supply may be configured to be coupled in parallel with the one or more batteries 460. The alternate DC power source and/or the external DC power supply may be used to perform the same and/or similar functions as the one or more batteries 460.

The motor drive unit 400 (e.g., the motor drive PCB circuit 402) may include a motor drive circuit 412 (e.g., an H-bridge drive circuit) that receives the battery voltage VBATT and may generate a pulse-width modulated (PWM) voltage V_{PWM} for driving the motor 410. While not shown in FIG. 14, the motor drive unit 400 (e.g., the motor drive PCB circuit 402) may comprise a power converter circuit (e.g., a boost converter circuit) coupled between the batteries 460 and the motor drive circuit 412 for receiving the battery voltage VBATT and generating a boosted voltage that may be received by the motor drive circuit 412 for driving the motor 410. The motor drive unit 400 (e.g., the motor drive PCB circuit 402) may also include a power supply 414 that may receive the battery voltage VBATT and generate a supply voltage V_{CC} for powering the low-voltage circuitry of the motor drive unit 400.

The motor drive unit 400 (e.g., the motor drive PCB circuit 402) may include a control circuit 420 for controlling the operation of the motor 410. The control circuit 420 may include, for example, a microprocessor, a programmable logic device (PLD), a microcontroller, an application specific integrated circuit (ASIC), a field-programmable gate array (FPGA), or any suitable processing device or control circuit. The control circuit 420 may be configured to generate one or more drive signals V_{DR} for controlling the motor drive circuit 412. The one or more drive signals V_{DR} may be configured to control a rotational speed and/or a direction of rotation of the motor 410. The control circuit 420 may be configured to control the motor 410 to adjust a present position P_{PRES} of the flexible material of the motorized window treatment between a raised position PRAISED (e.g., a fully-raised position) and a lowered position P_{LOWERED} (e.g., a fully-lowered position).

The motor drive unit 400 (e.g., the motor drive PCB circuit 402) may include a rotational position sensing circuit 422, such as, for example, a Hall effect sensor (HES) circuit, which may be configured to generate first and second rotational position sensing signals V_{S1}, V_{S2} (e.g., Hall effect sensor signals). The first and second rotational position sensing signals V_{S1}, V_{S2} may indicate the rotational speed and/or the direction of the motor 410 to the control circuit 420. The rotational position sensing circuit 422 may include other suitable position sensors, such as, for example, magnetic, optical, and/or resistive sensors. The control circuit 420 may be configured to determine the rotational position of the motor 410 in response to the first and second rotational position sensing signals V_{S1}, V_{S2} generated by the rotational position sensing circuit 422. The control circuit 420 may be configured to determine a present position of the flexible material in response to the rotational position of the motor 410. The operation of a motor drive circuit and a rotational position sensing circuit of an example motor drive unit is described in greater detail in commonly-assigned U.S. Pat. No. 5,848,634, issued Dec. 15, 1998, entitled MOTORIZED WINDOW SHADE SYSTEM, and commonly-assigned U.S. Pat. No. 7,839,109, issued Nov. 23, 2010, entitled METHOD OF CONTROLLING A MOTORIZED WINDOW TREATMENT, the entire disclosures of which are hereby incorporated by reference.

The motor drive unit 400 (e.g., the motor drive PCB circuit 402) may comprise a memory 424 (e.g., a non-volatile memory). The memory 424 may be communicatively coupled to the control circuit 420 for the storage and/or retrieval of, for example, operational settings of the motor drive unit 400. In addition, the memory 424 may be configured to store software for execution by the control circuit 420 to operate the motor drive unit 400. The memory 424 may be implemented as an internal circuit of the control circuit 420 or as an external integrated circuit (IC). The memory 424 may comprise a computer-readable storage media or machine-readable storage media that maintains computer-executable instructions for performing one or more of the procedures and/or routines as described herein. For example, the memory 424 may comprise computer-executable instructions or machine-readable instructions that include one or more portions of the procedures and/or routines described herein. The control circuit 420 may access the instructions from memory 424 for being executed to cause the control circuit 420 to operate as described herein, or to operate one or more other devices as described herein. The memory 424 may comprise computer-executable instructions for executing configuration software. Further, the memory 424 may have stored thereon one or more settings and/or control parameters associated with the motor drive unit 400. For example, the present position of the flexible material and/or limits for controlling the position of the flexible material (e.g., the raised position PRAISED) and/or the lowered position P_{LOWERED}) may be stored in the memory 424.

The motor drive unit 400 (e.g., the motor drive PCB circuit 402) may include a communication circuit 430, such as a wireless communication circuit (e.g., the wireless communication circuit 243) that may allow the control circuit 420 to transmit and receive signals, e.g., wireless signals, such as radio-frequency (RF) signals. The communication circuit 430 may comprise an RF transceiver in electrical communication with an antenna 432 (e.g., the antenna element 310) for transmitting and/or receiving RF signals. In addition, the wireless communication circuit may comprise an RF transmitter for transmitting RF signals, an RF receiver for receiving RF signals. The antenna-system PCB circuit 404 may comprise a matching network circuit 434 (e.g., the matching network circuit 346). The communication circuit 430 may be configured to be in electrical communication with the antenna 432 via the matching network circuit 434. The matching network circuit 434 may be configured to optimize the performance of the communication circuit 430 and/or the antenna 432. For example, the matching network circuit 434 may be configured to match an impedance of the antenna 432 to an impedance of the communication circuit 430 to obtain a maximum transfer of power between the communication circuit 430 and the antenna 432. The matching network circuit 434 may comprise one or more inductors and/or one or more capacitors. For example, the matching network circuit 434 may include, for example, an inductor-capacitor matching network, such as an inductor-capacitor (LC) filter circuit.

The control circuit 420 may be configured to control the motor 410 to control the movement of the flexible material in response to a shade movement command received in signals received via the communication circuit 430 from a remote control device. During a configuration procedure (e.g., an association procedure), the motor drive unit 400 may be associated with the remote control device, such that the motor drive unit 400 may be responsive to the messages transmitted by the remote control device (e.g., via wireless signals). For example, the motor drive unit 400 may comprise an actuator 426 (e.g., a mechanical tactile switch) that may be actuated in response to actuation of a button (e.g., the button 268) to cause the control circuit 420 to enter the configuration mode. In addition, the motor drive unit 400 may be configured with one or more operational settings (e.g., preset positions between the raised position and the lowered position) during the configuration procedure. The motor drive unit 400 may include a light source 428 that may be illuminated by the control circuit 420, for example, to provide feedback to the user of the motorized window treatment (e.g., during the configuration mode to indicate that the motor drive unit is in the configuration mode). The light source 428 may comprise one or more light-emitting diodes (LEDs).

What is claimed is:

1. A motor drive unit for a motorized window treatment, the motorized window treatment having a roller tube configured to windingly receive a flexible material and to be rotated to raise and lower the flexible material, the motor drive unit comprising:
a housing configured to be received within a cavity of the roller tube;
a motor located within the housing and configured to rotate the roller tube;
a first printed circuit board located within the housing, the first printed circuit board having mounted thereto drive circuitry for controlling the motor and a wireless communication circuit for communicating messages;
an antenna element configured to transmit and receive wireless signals; and
a second printed circuit board secured within the housing, the second printed circuit board comprising an electrical conductor that extends along a length of a front side of the second printed circuit board, the electrical conductor enabling electrical communication between the antenna element and the wireless communication circuit mounted to the first printed circuit board, the second printed circuit board further comprising a first ground plane on a rear side of the second printed circuit board, the first ground plane in electrical communication with a circuit common of the first printed circuit board;
wherein the wireless communication circuit is configured to receive messages via the wireless signals received by the antenna element and transmit messages via the wireless signals transmitted by the antenna element.

2. The motor drive unit of claim 1, wherein the second printed circuit board further comprises a second ground plane having a first portion located on a first side of the electrical conductor and a second portion located on a second side of the electrical conductor on the front side of the second printed circuit board.

3. The motor drive unit of claim 2, wherein the motor drive unit comprises an end portion configured to be mounted to a mounting bracket of the motorized window treatment, and the antenna is located adjacent to the end portion.

4. The motor drive unit of claim 3, wherein the antenna element comprises a wire wrapped around the housing of the motor drive unit.

5. The motor drive unit of claim 4, wherein the housing comprises at least one channel formed on a surface of the housing, and the wire of the antenna element is configured to be received within the at least one channel when wrapped around the housing.

6. The motor drive unit of claim 5, wherein the housing comprises a bearing assembly for rotatably coupling the motor drive unit to the roller tube, such that the roller tube is configured to rotate around the motor drive unit, the bearing assembly made of a non-conductive material, the antenna element wrapped around the motor drive unit within an area that surrounds a circumference of the motor drive unit and falls within an area defined by the bearing assembly.

7. The motor drive unit of claim 6, wherein the channel is formed on an inner bearing of the bearing assembly of the housing.

8. The motor drive unit of claim 4, wherein, when the end portion is mounted to the mounting bracket, a gap is defined between the roller tube and the mounting bracket, and wherein the electrical conductor of the antenna element is wrapped around the housing of the motor drive unit adjacent to the gap between the roller tube and the mounting bracket.

9. The motor drive unit of claim 8, wherein at least a portion of the antenna element is aligned with the gap between the roller tube and the mounting bracket.

10. The motor drive unit of claim 3, further comprising:
a coaxial cable electrically connected between the second printed circuit board and the first printed circuit board for electrically coupling the wireless communication circuit to the antenna element.

11. The motor drive unit of claim 10, wherein the housing defines a cavity extending from the end portion of the motor drive unit to the first printed circuit board, the cavity configured to receive one or more batteries for powering the drive circuitry and the wireless communication circuit mounted to the first printed circuit board.

12. The motor drive unit of claim 11, wherein the second printed circuit board is mounted to the housing within the cavity, and the coaxial cable extends from the second printed circuit board to the first printed circuit board within the cavity.

13. The motor drive unit of claim 12, further comprising:
a battery holder configured to hold the one or more batteries and to be received within the cavity of the housing, such that the second printed circuit board is located between the battery holder and the housing.

14. The motor drive unit of claim 13, further comprising:
a fin extending from an inner surface of the housing proximate to the first printed circuit board, such that a pocket is defined between the fin and the inner surface of the housing,
wherein the coaxial cable is configured to be located within the pocket as the coaxial cable extends between the second printed circuit board and the first printed circuit board.

15. The motor drive unit of claim 14, wherein the fin is configured to prevent interference between the battery holder and the coaxial cable.

16. The motor drive unit of claim 13, wherein the second printed circuit board is received in a recess in an inner surface of the housing.

17. The motor drive unit of claim 10, wherein the second printed circuit board comprises a first end located towards the end portion of the motor drive unit and a second end located towards the first printed circuit board, the antenna element electrically coupled to the second printed circuit board adjacent to the first end and the coaxial cable electrically coupled to the second printed circuit board adjacent to the second end.

18. The motor drive unit of claim 17, wherein further comprising:
a matching network circuit mounted to the second printed circuit board on the front side and at the first end of the second printed circuit board, the matching network circuit in electrical communication with the antenna element and the electrical conductor on the front side of the second printed circuit board.

19. The motor drive unit of claim 18, further comprising:
a first connector mounted to the second printed circuit board adjacent to the second end; and
a second connector mounted to the first printed circuit board,
wherein the coaxial cable is electrically connected between the first and second connectors.

20. The motor drive unit of claim 19, wherein the second printed circuit board comprises a transmission line portion that extends between the matching network circuit and the electrical conductor, the transmission line portion including the electrical conductor and the first ground plane on the rear side and the second ground plane on the front side of the second printed circuit board.

21. The motor drive unit of claim 18, wherein the second printed circuit board comprises a through-hole adjacent to the first end, the antenna element configured to extend through the through-hole and be electrically connected to the through-hole.

22. The motor drive unit of claim 1, wherein the antenna element is configured to be electromagnetically coupled to the roller tube of the motorized window treatment when the roller tube is made of a conductive material.

23. The motor drive unit of claim 2, wherein the second printed circuit board is made from a rigid material.

24. The motor drive unit of claim 23, wherein at least the first ground plane operates as a counterpoise of the antenna element, and the first printed circuit board is configured to rigidly support the second ground plane.

25-74. (canceled)
